(19) United States
(12) Patent Application Publication
(10) Pub. No.: US 2009/0170276 A1
(43) Pub. Date: Jul. 2, 2009

(54) Method of Forming Trench of Semiconductor Device

(75) Inventor: Choong Bae Kim, Yongin-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/147,183

(22) Filed: Jun. 26, 2008

(30) Foreign Application Priority Data
Dec. 27, 2007 (KR) 2007-138818

(51) Int. Cl. H01L 21/764

(52) U.S. Cl. 438/421; 257/E21.573

(57) ABSTRACT

The present invention relates to a method of forming trenches of a semiconductor device. According to the method, a hard mask pattern is formed on a semiconductor substrate so that an isolation region of the semiconductor substrate is opened. First trenches are formed in the isolation region by performing a first etch process employing the hard mask pattern. A spacer is formed on sidewalls of the first trenches. Second trenches, having a depth deeper than that of the first trenches, are formed in the isolation region by performing a second etch process employing the hard mask pattern.

### CROSS-REFERENCES TO RELATED APPLICATIONS

The present application claims priority to Korean patent application number 10-2007-0138818, filed on Dec. 27, 2007, which is incorporated by reference in its entirety.

### BACKGROUND OF THE INVENTION

The present invention relates to a method of forming trenches of a semiconductor device and, more particularly, to a method of forming trenches of a semiconductor device, which can form trenches in an isolation region using a shallow trench isolation (STI) method.

Generally, a semiconductor device formed in a silicon wafer includes isolation regions for electrically isolating semiconductor elements. In particular, with the high integration and miniaturization of semiconductor devices, research has been done on a reduction in the size of each individual element and also the isolation region. This is because the formation of the isolation region is an initial process step of the entire manufacturing process and greatly decides the size of an active region and process margin of post-process steps.

A field oxide layer is formed in this isolation region by a typical method, such as local oxidation of silicon (LOCOS) or profiled grove isolation (PGI), so that the active region is defined. In the LOCOS method, a nitride layer, that is, an oxidization-prevention mask to define the active region is formed on a semiconductor substrate and then patterned to thereby expose some of the semiconductor substrate. The exposed semiconductor substrate is oxidized to form the field oxide layer that is used as the isolation region. The LOCOS method is advantageous in that the process is simple and wide and narrow portions can be separated at the same time. However, the LOCOS method is disadvantageous in that a bird's beak occurs due to lateral oxidization, which resultantly widens the width of the isolation region, and the effective areas of source/drain regions can be reduced. The LOCOS method is also disadvantageous in that crystalline defects are generated in the silicon substrate because stress according to a difference in the coefficient of thermal expansion is concentrated on the corners of the oxide layer when the field oxide layer is formed and, therefore, the leakage current is a lot. Further, recently, with the high integration of semiconductor devices, the design rule is decreased and therefore the size of semiconductor elements and isolation layers for isolating the semiconductor elements is shrunk as much as the same scale. Accordingly, a typical isolation method such as LOCOS has reached its limits.

A STI method, that is, one of isolation layer formation methods for solving the above disadvantages is described below. First, material having an etch selectivity different from that of a semiconductor substrate, for example, a nitride layer is formed on the semiconductor substrate. In order to use the nitride layer as a hard mask pattern, the nitride layer is patterned to form a nitride layer pattern. Trenches are formed by etching the semiconductor substrate to a specific depth using an etch process employing the nitride layer pattern. The trenches are gap-filled with an insulating layer such as an oxide layer. Here, since it is difficult to gap-fill fully the trenches at once, the gap-fill process is repeatedly performed twice or more in order to gap-fill fully the trenches. Next, insulating material formed on a surface is removed using a chemical mechanical polishing (CMP) method, so that isolation layers are formed in the trenches.

The STI method is advantageous in that it can form an isolation layer having a micro width. However, with the higher integration and ultra-miniaturization of semiconductor devices, there is a tendency that the width of a trench is gradually narrowed. Accordingly, it becomes an important issue to gap-fill the trenches without voids when gap-filling the trenches with insulating material.

FIG. 2 is a scanning electron microscope (SEM) photograph showing the cross section of trenches formed according to a prior art.

Referring to FIG. 2, as the width of a trench formed is gradually narrowed, there is a case where a bowing profile occurs at a portion A on an upper portion of the trench. In this case, since the upper width of the trench is further narrowed, voids can occur within an isolation layer when the isolation layer is formed by gap-filling the trench with insulating material. Voids formed within the isolation layer are exposed through subsequent etch processes, which may damage the isolation layer or degrade the characteristics of the isolation layer.

### BRIEF SUMMARY OF THE INVENTION

The present invention is directed towards a method of forming trenches of a semiconductor device, in which a first etch process is performed up to a depth where a bowing profile begins to form. A spacer may be formed on sidewalls of the trenches, and a second etch process may then be performed up to a desired depth using the spacer as an etch-prevention layer in order to complete the formation of the trenches in the semiconductor substrate. The result is formation of the trenches without bowing profiles.

According to a method of forming trenches of a semiconductor device in accordance with the present invention, a hard mask pattern may be formed on a semiconductor substrate so that an isolation region of the semiconductor substrate is opened. First trenches may be formed in the isolation region by performing a first etch process employing the hard mask pattern. A spacer may be formed on sidewalls of the first trenches. Second trenches, having a depth deeper than that of the first trenches, may be formed in the isolation region by performing a second etch process employing the hard mask pattern.

The spacer may be formed from materials having an etch selectivity different from that of the semiconductor substrate. The spacer may be formed of an oxide layer or a nitride layer. The spacer may be formed to a thickness of 10 angstroms to 50 angstroms. The formation of the spacer may include forming the spacer layer over the hard mask pattern including the first trenches, and forming the spacer on sidewalls of the first trenches by performing an anisotropic etch process on the spacer layer so that the spacer layer remains only on the sidewalls of the first trenches. The spacer layer may be formed to a thickness of 10 angstroms to 200 angstroms. Each of the first trenches can be formed to a dept of 500 angstroms to 2000 angstroms.

### BRIEF DESCRIPTION OF THE DRAWINGS

FIGS. 1A to 1E are cross-sectional view illustrating a method of forming trenches of a semiconductor device in accordance with a preferred embodiment of the present invention; and

FIG. 2 is a SEM photograph showing the cross section of trenches formed according to a prior art.

### DESCRIPTION OF SPECIFIC EMBODIMENT

Now, specific embodiments according to the present invention will be described with reference to the accompanying drawings. However, the present invention is not limited to the disclosed embodiments, but may be implemented in various ways. The embodiments are provided to complete the disclosure of the present invention and to allow those having ordinary skill in the art to understand the scope of the present invention. The present invention is defined by the category of the claims.

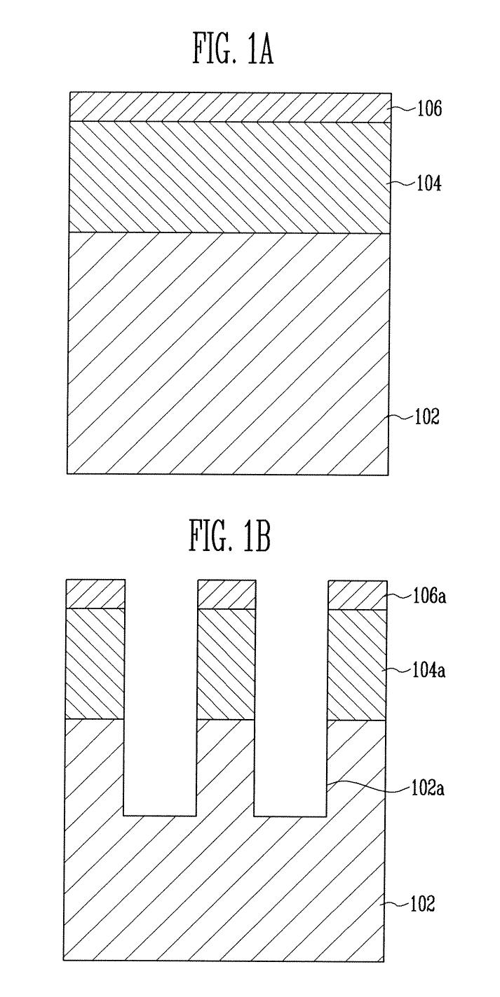

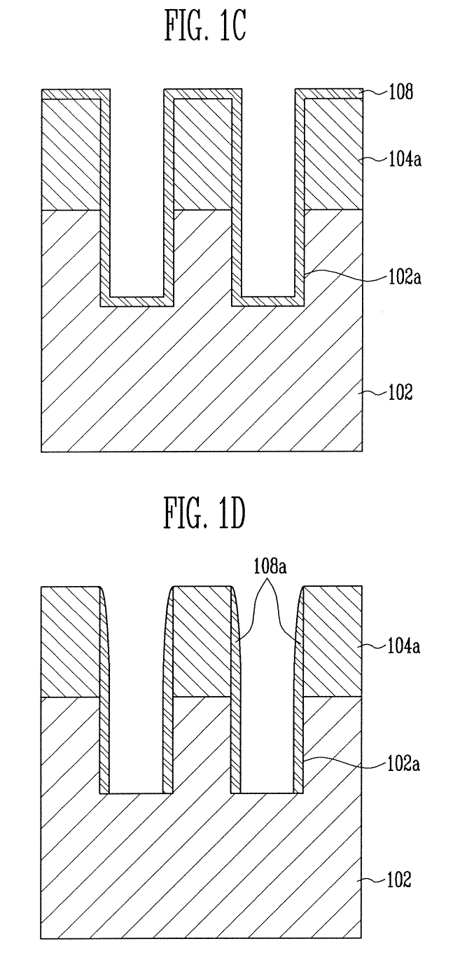

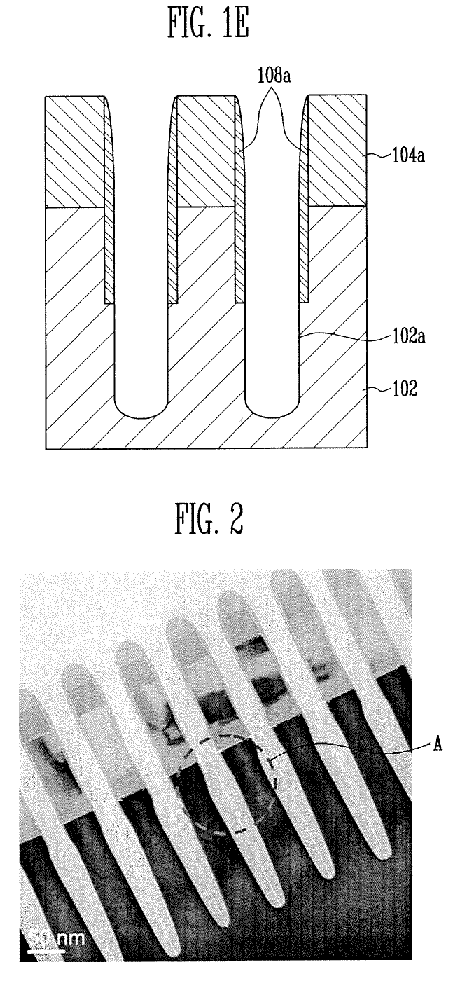

FIGS. 1A to 1E are cross-sectional views illustrating a method of forming trenches of a semiconductor device in accordance with preferred embodiments of the present invention.

Referring to FIG. 1A, a screen oxide layer (not shown) is formed on a semiconductor substrate 102. A well ion implantation process or a threshold voltage ion implantation process is performed on the semiconductor substrate 102. The well ion implantation process is performed in order to form a well region (not depicted) in the semiconductor substrate 102. The threshold voltage ion implantation process is performed to control the threshold voltage of a semiconductor element such as a transistor. Here, the screen oxide layer (not shown) functions to prevent damage to the interface of the semiconductor substrate 102 when the well ion implantation process or the threshold voltage ion implantation process is performed. Thus, the well region is formed in the semiconductor substrate 102. The well region can have a triple structure.

After the screen oxide layer (not shown) is removed, a hard mask layer 104, which will be used in an etch process for forming trenches, is formed on the semiconductor substrate 102. The hard mask layer 104 can be formed from materials having an etch selectivity different from that of the semiconductor substrate 102, such as a stacked layer of a nitride layer and an oxide layer. Meanwhile, although not shown in the drawings, a buffer layer may be further formed between the semiconductor substrate 102 and the hard mask.

Next, a photoresist layer 106 is formed on the hard mask layer 104. The photoresist layer 106 is used as an etch mask for patterning the hard mask layer 104.

Referring to FIG. 1B, exposure and development processes are performed on the photoresist layer (refer to 106 of FIG. 1A), thus forming a photoresist pattern 106a so that an upper portion of the isolation region of the semiconductor substrate 102 can be opened. The hard mask layer (refer to 104 of FIG. 1A) is patterned by performing an etch process using the photoresist pattern 106a as an etch mask, thus forming a hard mask pattern 104a. Accordingly, the hard mask pattern 104a through which an upper portion of the isolation region of the semiconductor substrate 102 is opened is formed.

Next, trenches 102a are formed in the isolation region of the semiconductor substrate 102 by performing a first etch process using the photoresist pattern 106a and the hard mask pattern 104a as an etch mask. At this time, each formed trench 102a can have a depth up to where a bowing profile begins forming on sidewalls of the trench when an etch process for forming a general trench is performed, for example, 500 angstroms to 2000 angstroms. That is, the first etch process is performed before a bowing profile is formed on the sidewalls of the trench 102a, so that the bowing profile is not formed on the sidewalls of the trench 102a.

Next, a photoresist strip process is performed in order to remove the photoresist pattern 106a and a cleaning process is then carried out. Meanwhile, although, in the present invention, it has been described that the photoresist pattern 106a is removed after the first etch process, the photoresist strip process for removing the photoresist pattern 106a and the cleaning process may be performed after the hard mask pattern 104a is formed.

Referring to FIG. 1C, a spacer layer 108 is formed on the hard mask pattern 104a including the trenches 102a. The spacer layer 108 can be formed to a thickness, which can maintain a step formed by the trenches 102a, for example, 10 angstroms to 200 angstroms. The spacer layer 108 can be formed from materials having an etch selectivity different from that of the semiconductor substrate 102, for example, an oxide layer or a nitride layer.

Referring to FIG. 1D, an anisotropic etch process is performed on the spacer layer (refer to 108 of FIG. 1C) and a cleaning process is then performed. Accordingly, the portion of the spacer layer (refer to 108 of FIG. 1C) formed at the bottoms of the trenches 102a and on the upper portions of the hard mask patterns 104a is removed, but the portion of the spacer layer (refer to 108 of FIG. 1C) on the sidewalls of the trenches 102a remains, thus forming a spacer 108a. At this time, the spacer 108a that is finally formed can have a thin thickness, for example, 10 angstroms to 50 angstroms in such a manner that a narrowing width of the trench 102a, when gap-filling the trenches 102a with insulating material, can be minimized.

Referring to FIG. 1E, a second etch process using the hard mask pattern 104a as an etch mask is performed. Here, the spacer 108a formed on the sidewalls of the trenches 102b functions as an etch-prevention layer, so that the sidewalls of the trenches 102b are not etched. Further, the isolation region of the exposed semiconductor substrate 102 is etched, so that the trenches 102b having a deeper depth can be formed.

As described above, a first etch process may be performed on the semiconductor substrate in order to form trenches up to a depth where bowing profiles begin to form on sidewalls of the trenches. A spacer may be formed on the trench sidewalls using materials having an etch selectivity different from that of the semiconductor substrate. A second etch process may then be performed on the semiconductor substrate again in order to make the trenches deeper. Thus, micro trenches without bowing profiles can be formed. Accordingly, in subsequent processes, voids are not generated when the trenches are gap-filled with insulating material and, therefore, isolation layers without defects can be formed.

In a method of forming trenches of a semiconductor device in accordance with embodiments of the present invention, trenches without bowing profiles can be formed and therefore voids are not generated when gap-filling the trenches with insulating material. According, reliable isolation layers can be formed and high-performance semiconductor devices can be fabricated.

The embodiment disclosed herein has been proposed to allow a person skilled in the art to easily implement the present invention, and the person skilled in the part may implement the present invention in various ways. Therefore, the scope of the present invention is not limited by or to the embodiment as described above, and should be construed to be defined only by the appended claims and their equivalents.

What is claimed is:

1. A method of forming trenches of a semiconductor device, the method comprising:
forming a hard mask pattern on a semiconductor substrate so that an isolation region of the semiconductor substrate is opened;
forming first trenches in the isolation region by performing a first etch process employing the hard mask pattern;
forming a spacer on sidewalls of the first trenches; and
forming second trenches, having a depth deeper than that of the first trenches, in the isolation region by performing a second etch process employing the hard mask pattern.

2. The method of claim 1, wherein the spacer is formed from materials having an etch selectivity different from that of the semiconductor substrate.

3. The method of claim 1, wherein the spacer is formed of an oxide layer or a nitride layer.

4. The method of claim 1, wherein the spacer is formed to a thickness of 10 angstroms to 50 angstroms.

5. The method of claim 1, wherein the formation of the spacer comprises:
forming the spacer layer over the hard mask pattern including the first trenches; and
forming the spacer on sidewalls of the first trenches by performing an anisotropic etch process on the spacer layer so that the spacer layer remains only on the sidewalls of the first trenches.

6. The method of claim 5, wherein the spacer layer is formed to a thickness of 10 angstroms to 200 angstroms.

7. The method of claim 1, wherein each of the first trenches is formed to a dept of 500 angstroms to 2000 angstroms.

8. The method of claim 1, wherein forming a spacer on sidewalls of the first trench comprises forming etch prevention layers.

9. The method of claim 1, wherein forming first trenches comprises forming first trenches to a depth corresponding to a depth where a bow profile initiates.
